(19) United States
(12) Patent Application Publication
(10) Pub. No.: US 2012/0000511 A1
(43) Pub. Date: Jan. 5, 2012

(54) METHOD OF MANUFACTURING CRYSTALLINE SILICON SOLAR CELLS USING EPITAXIAL DEPOSITION

(75) Inventors: James M. Gee, Albuquerque, NM (US); Charles Gay, Westlake Village, CA (US)

(73) Assignee: APPLIED MATERIALS, INC., Santa Clara, CA (US)

(21) Appl. No.: 13/106,721

(22) Filed: May 12, 2011

Related U.S. Application Data
(60) Provisional application No. 61/334,058, filed on May 12, 2010.
(60) Provisional application No. 61/350,874, filed on Jun. 2, 2010.

(51) Int. Cl. H01L 31/0264; H01L 31/0236; H01L 31/042

(52) U.S. Cl. 136/249; 136/261; 438/65; 257/E31.13

(57) ABSTRACT

Embodiments of the invention provide a thin single crystalline silicon film solar cell and methods of forming the same. The method includes forming a thin single crystalline silicon layer on a silicon growth substrate, followed by forming front or rear solar cell structures on and/or in the thin single crystalline silicon film. The method also includes attaching the thin single crystalline silicon film to a mechanical carrier and then separating the growth substrate from the thin single crystalline silicon film along a cleavage plane formed between the growth substrate and the thin single crystalline silicon film. Front or rear solar cell structures are then formed on and/or in the thin single crystalline silicon film opposite the mechanical carrier to complete formation of the solar cell.

### CROSS-REFERENCE TO RELATED APPLICATIONS

This application claims benefit of U.S. Provisional Patent Application Ser. No. 61/334,058 (APPM/015351L), filed May 12, 2010, and U.S. Provisional Patent Application Ser. No. 61/350,874 (APPM/015398L), filed Jun. 2 2010, each of which are herein incorporated by reference.

### BACKGROUND OF THE INVENTION

1. Field of the Invention

Embodiments of the invention relate to solar cells and the fabrication of solar cells. In particular, embodiments of the invention relate to thin crystalline-silicon film solar cells.

2. Description of the Related Art

Photovoltaic (PV) devices or solar cells are devices which convert sunlight into direct current (DC) electrical power. With traditional energy source prices on the rise, there is a need for a low-cost way of producing electricity using a low-cost solar cell device. Conventional solar cell manufacturing processes are highly labor intensive and have numerous interruptions that can affect the production line throughput, solar cell cost, and device yield. Moreover, crystalline-silicon solar cells, while generally more efficient, are also more expensive to fabricate than other types of solar cells. One alternative to crystalline silicon solar cells is thin-film solar cells, which typically have a photoelectric conversion unit that may include several types of silicon films, including microcrystalline silicon films (μc-Si), amorphous silicon films (a-Si), and polycrystalline silicon films (poly-Si). While thin-film solar cells are generally less expensive to fabricate, they are generally not as efficient as crystalline-silicon solar cells.

Crystalline-silicon solar cells are electrically connected into a circuit to produce voltages acceptable for system performance. The solar cell circuit also provides other necessary functions like bypass diodes to limit internal heating when a solar cell in the circuit is shaded. A photovoltaic module encloses the solar cell circuit in a package for environmental protection. The photovoltaic module typically encapsulates the solar cell circuit with a glass cover, a bonding material, and a backsheet. The photovoltaic module typically also includes a “junction box” where electrical connections to other components of the complete photovoltaic system are made.

The typical fabrication sequence for photovoltaic modules includes assembly of the solar cell circuit, assembly of a layered structure that includes glass, bonding material, the solar cell circuit, more bonding material, and a backsheet, and lamination of the layered structure. The final steps include installation of the module frame and junction box, and testing of the module. The solar cell circuit is typically manufactured using automated tools (“stringer/tabbers”) that connect the solar cells in electrical series with copper (Cu) flat ribbon wires (“interconnects”). Several strings of series-connected solar cells are then electrically connected with wide Cu ribbons (“busses”) to complete the circuit. These busses also bring the current to the junction box from several points in the circuit for the bypass diodes and for connection to the cables. The majority of solar cells today have contacts on opposite surfaces.

Back-contact solar cells have both the negative and positive polarity contacts on the back surface. Location of both polarity contacts on the same surface simplifies the electrical interconnection of the solar cells. It also enables new assembly approaches and new module designs, such as “Monolithic module assembly” or “MMA” which refers to assembly of the solar cell electrical circuit and the laminate in the same step.

A typical monolithic module assembly starts with a backsheet having a patterned electrical conductor layer formed thereon. Production of such patterned conductor layers on flexible large-area substrates is well known from the printed-circuit board and flexible-circuit industries. The back-contact cells are placed on this backsheet with a pick-and-place tool. Such tools are well known and are very accurate with high throughput. The solar cells make electrical connection to the patterned electrical conductors on the back sheet during the lamination step; the laminated package and electrical circuit are thus produced in a single step and with simple automation. The backsheet includes materials like solders or conductive adhesives (electrical connection material) that form the electrical connection during the lamination temperature-pressure cycle. The backsheet and/or cells could optionally include an electrical insulator layer to prevent shorting of the electrical conductors on the backsheet with the conductors on the solar cell. A polymer layer can also be provided between the backsheet and the solar cell for the encapsulation. This layer provides low-stress adhesion of the backsheet to the solar cell. Open channels can be provided in this encapsulation layer where the electrical connection is made between the solar cells and the conductor layer.

Crystalline-silicon substrates for solar cells are commonly manufactured by growing an ingot and slicing the ingot into “wafers”. The slicing process is very wasteful due to material lost during the cutting operation, sometimes referred to as KERF or KERF loss. In addition, the ingot growth requires considerable energy and uses other consumables that increase the cost. Finally, the ingot uses silicon feedstock that is commonly produced by hydrogen reduction of trichlorosilane. The reduction reaction is energy and capital intensive, which also increases the cost. The net result is that the silicon wafer is the single largest cost component in a photovoltaic module using crystalline-silicon solar cells.

Therefore, there is a need for improved crystalline-silicon solar cells and module assembly with reduced fabrication costs.

### SUMMARY OF THE INVENTION

The present invention generally provides solar cell devices and methods of forming solar cell devices. In one embodiment, the method includes forming a cleavage plane on a growth substrate, forming an epitaxial layer on the cleavage plane, forming portions of a solar cell structure on and/or in the epitaxial silicon bulk layer, attaching the epitaxial layer to a mechanical support opposite the growth substrate, separating the growth substrate from the epitaxial silicon bulk layer, and forming other solar cell features on and/or in the epitaxial silicon bulk layer opposite the mechanical support to complete formation of the solar cell structure.

In another embodiment, a solar cell includes an epitaxial silicon bulk layer formed using a growth susbtrate, the epitaxial silicon bulk layer having a front surface and a rear surface, a p-type emitter comprising a p-type dopant formed in the rear surface of the epitaxial silicon bulk layer, an n-type emitter comprising an n-type dopant formed in the rear surface of the epitaxial silicon bulk layer, p-type contacts connected to the p-type layer, and n-type contacts connected to the n-type layer.

In another embodiment, a method of forming a solar cell includes forming a porous layer having a cleavage plane on a growth substrate, processing at least a portion of the porous layer to form a crystalline layer, forming portions of a solar cell structure on and/or in the crystalline layer to form portions of a solar cell structure, attaching a mechanical support to the crystalline layer opposite the growth substrate, separating the growth substrate from the crystalline layer along the cleavage plane, and forming other solar cell features on and/or in the crystalline layer opposite the mechanical support to complete formation of the solar cell structure.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1K illustrate schematic cross-sectional views of a solar cell during different stages in fabrication sequence according to one embodiment of the invention.

FIGS. 2A-2F illustrate schematic cross-sectional views of a solar cell during different stages in fabrication sequence according to one embodiment of the invention.

FIGS. 3A-3L illustrate schematic cross-sectional views of a solar cell during different stages in a fabrication sequence according to another embodiment of the invention.

FIGS. 4A-4C illustrate schematic cross-sectional views of a solar cell during different stages in a fabrication sequence according to another embodiment of the invention.

FIGS. 5A-5C illustrate schematic cross-sectional views of a solar cell during different stages in a fabrication sequence according to another embodiment of the invention.

FIGS. 6A-6E illustrate schematic cross-sectional views of a solar cell during different stages in a fabrication sequence according to another embodiment of the invention.

FIG. 7 illustrates solar cells having a front and rear contact solar cell structure connected in series according to another embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the inventions generally provide thin single crystalline silicon film solar cells and the fabrication of thin single crystalline silicon films for solar cells using a silicon growth substrate. Embodiments of the inventions employ a growth substrate to form a thin single crystalline silicon film thereon, attach the thin single crystalline silicon film to a mechanical support, such as a “carrier” or “handle”, opposite the growth substrate, and separate the thin single crystalline silicon film from the growth substrate at some point during subsequent solar cell processing. Embodiments of the inventions describe several methods for fabricating solar cells and modules using thin single crystalline silicon films formed by using the growth substrate. The thin single crystalline silicon film is processed into solar cells, which solar cells may also be assembled into modules with the carrier.

Typically, single crystalline silicon solar cells have intensive capital costs, often due to the cost of manufacturing a single crystalline-silicon ingot and processing the ingot to form single crystalline-silicon substrates. An approach to greatly reduce the cost is to use thin single crystalline silicon films. Such films can be produced by chemical vapor deposition (CVD) on a single crystalline silicon substrate and then removed from the substrate by use of a pre-existing layer of weakness for separating the single crystalline silicon film from the substrate. The pre-existing layer of weakness can be produced using various methods, for example, by hydrogen implant and anneal or by a porous silicon etch. The process is much less expensive because it eliminates the cost of the silicon feedstock production step, eliminates the KERF loss in the slicing step, and eliminates the cost of the ingot growth. Moreover, the growth substrate may be reused multiple times to form more epitaxial single crystalline silicon film. In general, embodiments of the invention include growing thin crystalline silicon films epitaxially on a silicon growth substrate, which produces a single crystalline silicon film with good material quality.

The thin epitaxial single crystalline silicon films, which may be between 5 and 50 microns (μm) in thickness, are very difficult to process as stand-alone substrates. They may also bow very easily with stress after applying the metallization. Thin films may also be difficult to assemble into photovoltaic modules. Therefore, it is advantageous to process as much of the solar cell as possible while the thin crystalline-silicon film is still on the growth substrate. In that way, conventional cell fabrication processes may still be used on the thin silicon film to form a completed solar cell. After thin epitaxial single crystalline silicon film removal and subsequent bonding to the carrier, the temperature and chemical compatibility for solar cell and module fabrication may become constrained by the properties of the carrier and the material used for bonding the thin crystalline-silicon film to the carrier. Several different possible process sequences may be used to form solar cells from thin epitaxial single crystalline silicon film formed by using growth substrates.

### Back-junction Cell with Glass Superstrate

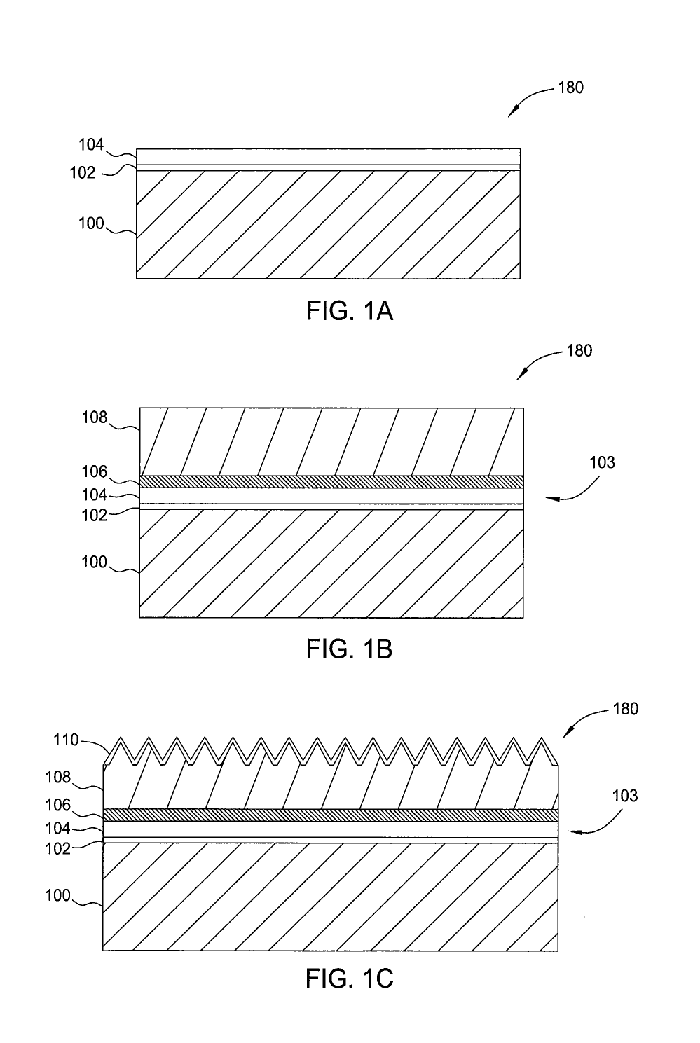

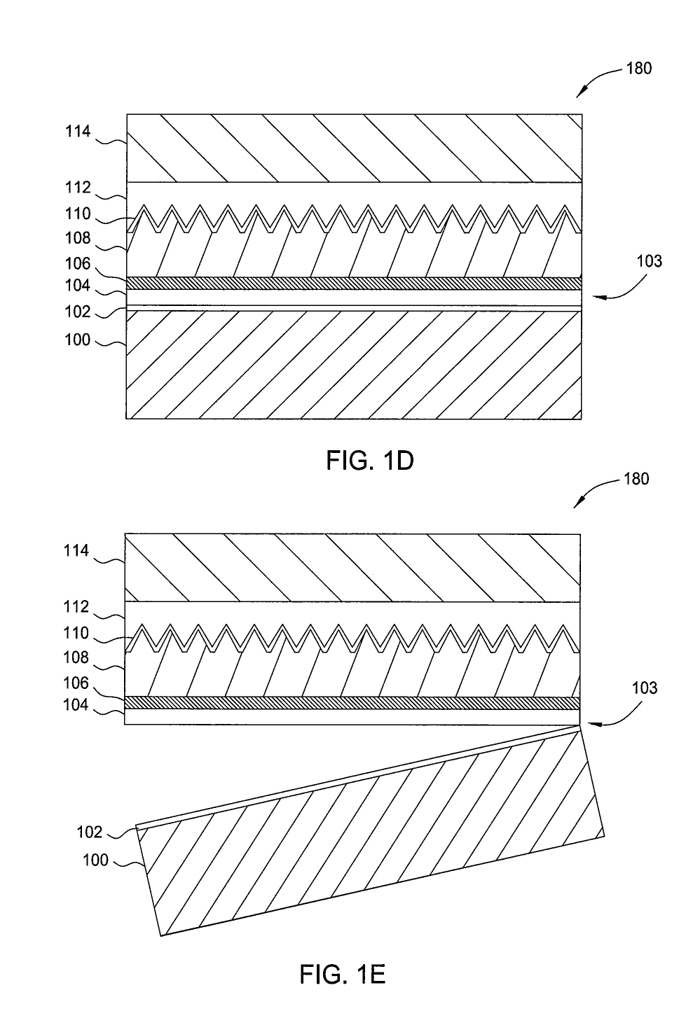

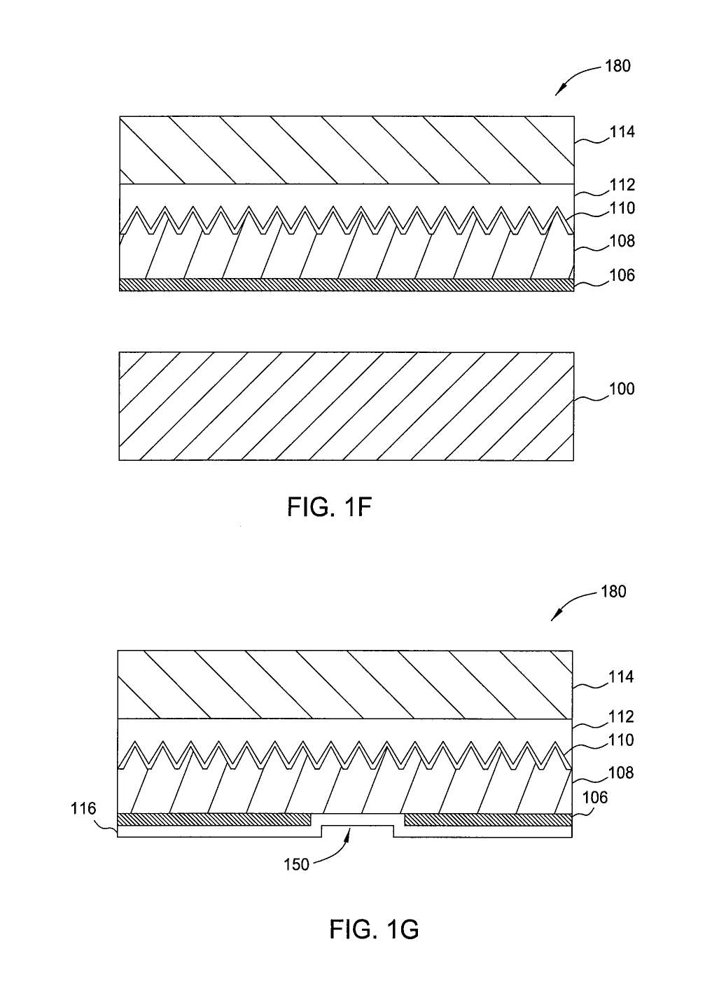

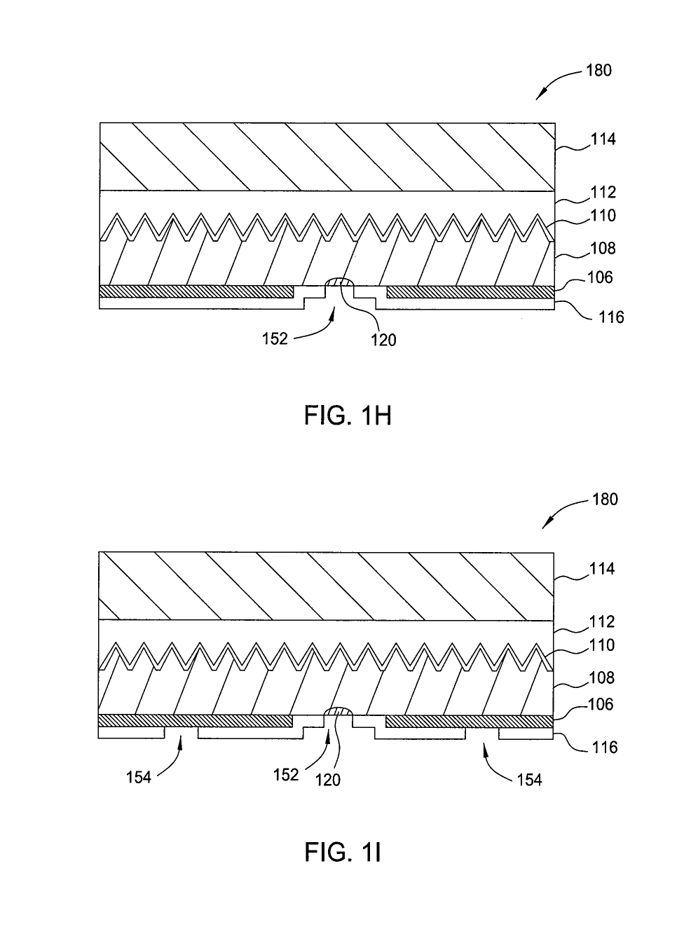

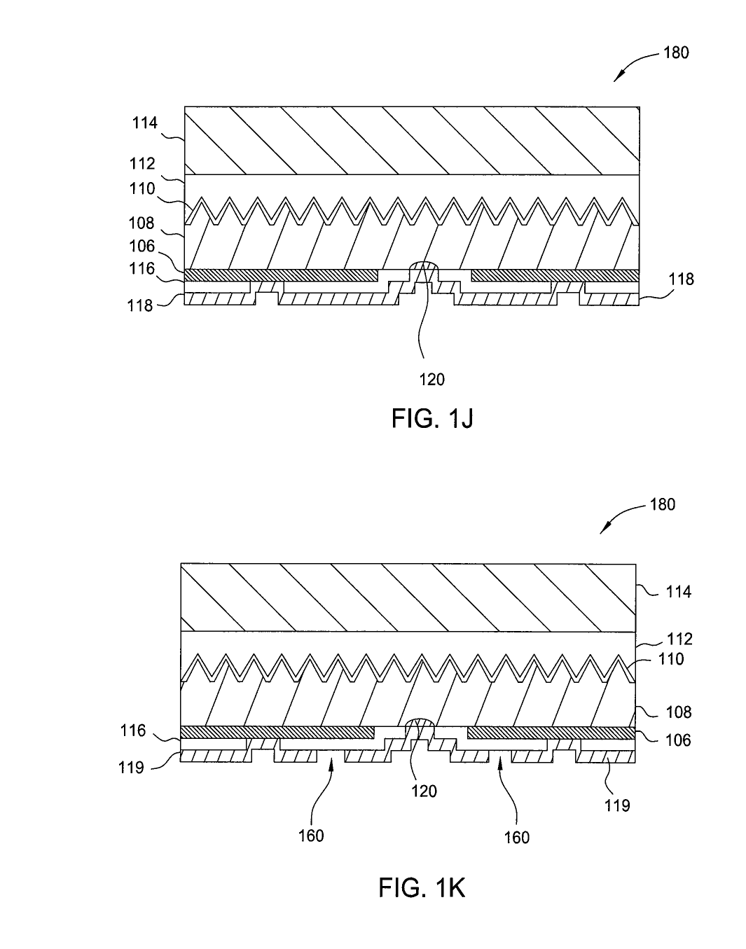

In one embodiment, a high-efficiency back-junction cell structure is formed using a thin single crystalline silicon film formed on a growth substrate and subsequently bonded to a glass superstrate. A representative process sequence will be described with reference to FIGS. 1A-1K, which illustrate schematic cross-sectional views of a solar cell structure during different stages in a processing sequence used to form a solar cell 180. The processes for forming the solar cell may be performed in a single process performed in one substrate processing chamber, or in multiple process steps performed in one or more processing chambers.

The process generally includes forming a doped epitaxial layer on a growth substrate, where the formed epitaxial layer becomes a thin solar cell substrate on which the rest of the solar cell device structures are formed. Thus, the epitaxial layer and/or silicon growth substrate may be further processed to form various features such as emitters and anti-reflective coating/passivation layers. The growth substrate is separated from the epitaxial layer, followed by completion of the solar cell production process, such as forming the back contacts. The growth substrate may then be reused to form more thin epitaxial single crystalline silicon films for more solar cells. In one embodiment, a silicon growth substrate may go through two dozen or more cycles of forming thin single crystalline silicon films for solar cells.

A growth substrate 100 may be a single crystalline Czochralski-grown p-type silicon substrate. Other types of doped or undoped single crystalline silicon substrates may also be used. The growth substrate 180 may be 0.7 millimeters or more thick, such as 1 millimeter thick. A thicker growth substrate allows for more reuse of the growth substrate since there is a small loss of the growth substrate each time the thin single crystalline silicon film is formed thereon and subsequently separated therefrom. The growth substrate 100 is a p-type substrate that has a resistivity of about 10 Ohms per square (Ω/□). The growth substrate 100 may be a heavily doped p-type substrate, such as p⁺ or p⁺⁺.

In order to make the growth substrate 100 reusable, a mechanically weak planar layer is formed so that a pre-existing layer of weakness or “cleavage plane” is disposed between the growth substrate 100 and a thin epitaxial single crystalline silicon film formed thereon. To that end, a porous layer 103 is formed on a growth substrate 100 (FIG. 1A). The porous layer 103 may be formed by electrochemical etching the growth substrate 100 using a silicon etch process where the growth substrate 100 serves as an anode immersed in an electrolytic solution and another material serves as the cathode, such as platinum. The electrolytic solution may comprise about 2 weight percent (wt %) of hydrofluoric acid (HF). The porous layer 103 is formed as current passes through the growth substrate 100.

Multiple porous layers having varying degrees of porosity may be formed into the top surface of the growth substrate 100 by tuning the etch chemistry and current density of the electrochemical etch process. For example, a top porous layer 104 having micro-pores may be formed on a bottom porous layer 102 having macro-pores. The bottom porous layer is a high porosity layer and the top porous layer is a low porosity layer. Thus, the bottom porous layer has a first porosity and the top porous layer has a second porosity where the first porosity is greater than the second porosity. A high porosity layer may be considered to have a porosity of 5-10% and a low porosity layer is less than that amount. Macro-pore diameters are considered to be in the micron scale range, while micro-pore diameters are less than a micron scale range. The low porosity top layer 104 may be between about 0.5 and 15 about micrometers (μm) thick, such as between about 1 and about 7 μm thick, and the high porosity bottom layer 102 may be between about 10 nanometers (nm) and about 5 μm thick. In one embodiment, the radius of the porosity of the low porosity top layer 104 is about 1 μm in size, and the radius of the porosity of the high porosity bottom layer 102 is greater than about 1 μm in size.

Changing the current density of the electrochemical silicon etch may be used to change the pore diameter in order to form a macro-pore or micro-pore layer. Macropores may be formed, for example, by applying an etching current density of around 3 milli-amperes (mA)/cm² at 20° C. for about 30 minutes for pore nucleation, followed by linearly increasing the current density from 3 mA/cm² to 20 mA/cm² within about 8 minutes. The current may be maintained at 20 mA/cm² for about 12 minutes to form a highly porous layer. Other methods of forming porous silicon known in the art may also be used.

In another embodiment, a “smart cut” process may be used to form a cleavage plane in the porous layer 103. The “smart cut” process includes implanting hydrogen ions at high energy in the porous layer 103. At the end of the depth range where all the hydrogen atoms are deposited, the hydrogen atoms recombine into H₂ molecules to form a weak cleavage plane in the porous layer 103 when the growth crystal 100 is annealed. The weakened layer in the porous layer 103 can be used in later process sequences to cleave the growth substrate 100 from the film(s) formed on the growth substrate 100.

Following formation of the cleavage plane, the growth substrate 100 and porous layer 103 is annealed in hydrogen (H₂) gas at a temperature from about 1,000° C. to about 1,200° C. for a period of about 30 minutes. Annealing tends to coalesce the low porosity micro-pore top layer 104 to form a single crystal or very nearly single crystal layer having a smooth surface. Thus, the low porosity top porous layer 104 becomes a seed layer for forming a silicon bulk layer 108 of epitaxial single crystalline silicon film, while the high porosity bottom porous layer 102 becomes a mechanically weak plane that will be used for separating the growth substrate 100 from the subsequently formed silicon bulk layer 108 of thin epitaxial single crystalline silicon film. The annealing process may be done in the same chamber used for formation of the silicon bulk layer 108.

Next, a silicon bulk layer 108 of thin epitaxial single crystalline silicon film is formed on the porous layer 103, for example on the low porosity top-layer 104, as shown in FIG. 1B. The silicon bulk layer 108 may be grown to between 10 to 50 microns thick, such as 40 microns thick and may be formed using chemical vapor deposition (CVD), physical vapor deposition (PVD), or atomic-layer deposition (ALD) processes including plasma enhanced processes e.g. PECVD, as well as other types of CVD, PVD, and ALD techniques. The silicon bulk layer 108 is doped with n-type dopants during the formation process. For example, in CVD processes, a dopant gas, such as phosphine for n-type dopants, may be included in the process gas mixture when depositing the silicon bulk layer 108. In PVD processes, the dopant may be a part of the target material that is deposited with the silicon bulk layer 108. Additionally, a post thermal treatment of the PVD deposited silicon film is used to recrystallize the film to form the silicon bulk layer 108 into a single crystalline film. Alternatively, formation of the silicon bulk layer 108 may be done by dipping the surface of the growth substrate 100 having the porous layer 103 into molten silicon to deposit a layer of a single crystalline silicon film on the porous layer 103.

The epitaxial formation of a thin film of silicon on the growth substrate 100 creates a silicon bulk layer 108 that has the same crystal structure of the growth substrate 100. Thus, a thin epitaxial single crystalline silicon film may be formed on the growth substrate using the porous layer 103 as a seed layer. As part of the formation process for the silicon bulk layer 108, a p-type layer 106 may also be formed on the low porosity top layer 104. The p-type layer 106 may be a heavily doped p⁺ layer using boron as a dopant. The p-type layer 106 forms a p-n junction with the n-type region of the silicon bulk layer 108, and will become the emitter on the rear surface of the completed solar cell. Other process sequences may form a p-type layer or an n-type layer depending on the solar cell type and structure. The p-type layer 106 may be 3-5 microns thick when initially formed but the final layer may be 1-2 microns thick after subsequent processing. The difference between initial and final thicknesses may be because it may take some time to nucleate and form high quality silicon films when forming a CVD epitaxial silicon film. Additionally, after separating the silicon growth substrate 100 from the film(s), there may be a residual porous silicon layer that requires removal without consuming the entire p-type layer 106.

The top surface of the silicon bulk layer 108 may then be etched to form a textured surface for increasing optical absorption in the solar cell as shown in FIG. 1C. An alkaline etchant may be used for forming the textured surface. The textured structure may also be further diffused with an n-type dopant, such as phosphorous, to form a heavily doped n⁺ region near the textured surface. This may be done by annealing the solar cell 180 at a temperature from between 830° C.-900° C. A phosphosilicate glass (PSG) may be formed on the top surface of silicon bulk layer 108 after annealing the phosphorous doped region, which PSG may then be etched off globally using an etchant, such as HF acid. The PSG is etched off the silicon bulk layer 108 to prepare the surface for further processing.

An anti-reflection coating (ARC) layer 110 may then be formed on the silicon bulk layer 108, as shown in FIG. 1C. In one embodiment the ARC layer 110 is a silicon nitride layer that may also be hydrogenated to form a passivation layer. The ARC layer 110 may be formed, for example, using CVD, PVD, or ALD processes. The ARC layer 110 may be formed using a low temperature process.

A mechanical support is then bonded to a surface of the silicon bulk layer 108 to provide a support for the films formed during a lift off process to remove the growth substrate 100. The mechanical support may comprise various types of substrates, some of which may be used only as a carrier to be later discarded during the subsequent solar cell or solar module process and others that may form a portion of the completed solar cell or solar module. For example, a superstrate, such as a glass superstrate 114, is bonded to the ARC layer 110, as shown in FIG. 1D. The glass superstrate 114 in this embodiment serves as the front side glass in the final solar cell structure.

The glass superstrate 114 may be bonded to the ARC layer 110 by using an adhesive, such as silicone, thereby forming an adhesive layer 112. When using silicone, the solar cell 180 may then be baked in an oven, such as a box oven, at 200° C. to complete the bonding process and cure the adhesive layer 112 to the glass superstrate 114. The bake may be for a longer time to ensure bonding of the silicone to the ARC layer 110 or silicon bulk layer 108, and the glass superstrate 114. Other appropriate adhesive materials known in the art may also be used. The glass superstrate 114 may be a thin sheet that is from 100 to 1,000 microns thick. For example, some possible types of glass may be float glass and glass used for flat panel displays.

The silicon growth substrate 100 is then separated from the partially formed solar cell 180, as shown in FIG. 1E. This may be done by cleaving the growth substrate from the partially formed solar cell 180 along the boundary between the low porosity top-layer 104 and the high porosity bottom-layer 102. The cleaving process may be performed by applying a thermal gradient to create a thermal stress or using mechanical means to create mechanical shock, so that the high porosity bottom-layer separates 102 from the low porosity top-layer 104. The silicon growth substrate 100 may then be cleaned and reused, as shown in FIG. 1F.

The rear surface of the partially formed solar cell, e.g. p-type layer 106, may then need to be etched and cleaned following separation from the silicon growth substrate 100 to remove residual porous material. Any remaining low porosity top-layer 104 may be removed from the p-type layer 106 by etching and cleaning the exposed rear surface, as shown in FIG. 1F.

The rear emitter is subsequently formed using various processes such as by patterning the p-type layer 106 to form the p⁺ emitter, as shown beginning at FIG. 1G. The p-type layer 106 may be patterned to expose portions of the silicon bulk layer 108. Patterning the p-type layer 106 may be performed by using laser ablation, laser chemical processing where a water-guided laser beam includes chemical etchants, lithographic processes such as screen printed resist and standard chemical etches, an etch gel such as an inkjet etchant printed paste, or other suitable patterning techniques known in the art. A portion of the p-type layer 106 is thereby removed, exposing the silicon bulk layer 108 in an area 150 chosen to form the n-type emitter 120. A passivation dielectric layer 116 is then formed over the p-type layer 106 and exposed portions of the silicon bulk layer 108.

Contact openings 152, 154 are patterned into the dielectric passivation layer as shown in FIGS. 1H and 1I. For example, the passivation dielectric layer 116 is patterned to form contact opening 152 and to expose the n-type doped silicon bulk layer 108, which may be done by laser patterning, water jet, printed etchant inks, or other patterning processes. An n-type emitter 120 is formed by doping the exposed portion of the silicon bulk layer 108. The n-type dopant may be phosphorous.

The doping process may be done using plasma doping process (e.g., P3i implant process available from Applied Materials Inc.) or a standard thermal diffusion process. Alternatively, the doping may be performed at low substrate temperature by using laser chemical processing or laser patterning. Laser chemical processing may include a water jet as an optical guide for the laser beam and dopant chemicals within the water jet, such as phosphorus dopant chemical. When the laser ablates the dielectric from the surface, it momentarily melts the silicon surface and enables simultaneous doping of the surface. In another embodiment, a dopant source may be deposited on the surface followed by laser ablation which enables simultaneous dopant of the surface. The passivation dielectric layer 116 is patterned again to form contact openings 154 to expose the p-type layer 106 for p-type contacts, which also may be done such as by laser patterning or by laser fired contact (LFC) methods.

The back contacts 119, such as p-type and n-type contacts, are then formed as illustrated in FIG. 1J-1K. The back contacts may be formed by deposition of a thin-film metallization layer 118. The thin-film metallization layer may be, for example, aluminum (Al) which may then be coated with a more bondable metal such as nickel (Ni). Metallization of the rear surface of the solar cell 180 may include metallization of the passivation dielectric layer 116 and exposed portions of the p-type layer (forming the p-type contacts) and n-type emitter 120 (forming n-type contacts). Next, the metallization layer 118 is patterned to form openings 160, thereby forming the back contacts 119, and forming positive and negative polarity grids. Suitable techniques may be used to pattern the metallization layer 118, such as etchant gels, photoresist lithography and etching, or printing a resist pattern with etchant and then stripping the resist. The thin-film metallization minimizes stress and is deposited at relatively low temperatures, although the conductivity may be limited. The p-type contacts and n-type contacts are thus electrically connected to the respective p-type emitters and n-type emitters formed in solar cell 180.

The back contacts 119 may be annealed or sintered at temperatures compatible with the rest of the films in the solar cell structure, such as 400° C. and below, for example between about 300° C. and about 400° C. The annealing or sintering may be done using non isothermal rapid thermal techniques, such as RTP systems, or a short heat pulse from one surface, or sub-band gap light and optical processing, so that the light and thus the heat is selectively absorbed by the contacts. The p-type contact may be done as a LFC which may eliminate the p-type contact patterning step, and use the laser firing step as an alternative.

The solar cell is then tested to ensure functionality. In one embodiment, a dielectric layer (not shown) might optionally be printed over the metallization layer and back contacts 119 to provide electrical isolation in a module assembly. A dielectric electrical isolation layer, sometimes referred to as an interlayer dielectric (ILD) layer, may be required for the module assembly. An ILD layer may be a printed solder resist type material, which prevents electrical shorts during module assembly. For example, during module assembly a relatively compliant electrically conductive adhesive (ECA) may be used. ECA's though have a tendency to spread and can short out the solar cell/module. The ILD layer may prevent shorting the solar cells/module. The ILD material may be a UV cured material enabling low temperature curing. The glass superstrate 114 and solar cell assembly may then be assembled into a photovoltaic module.

### Alternate Back junction Cell Formation Process

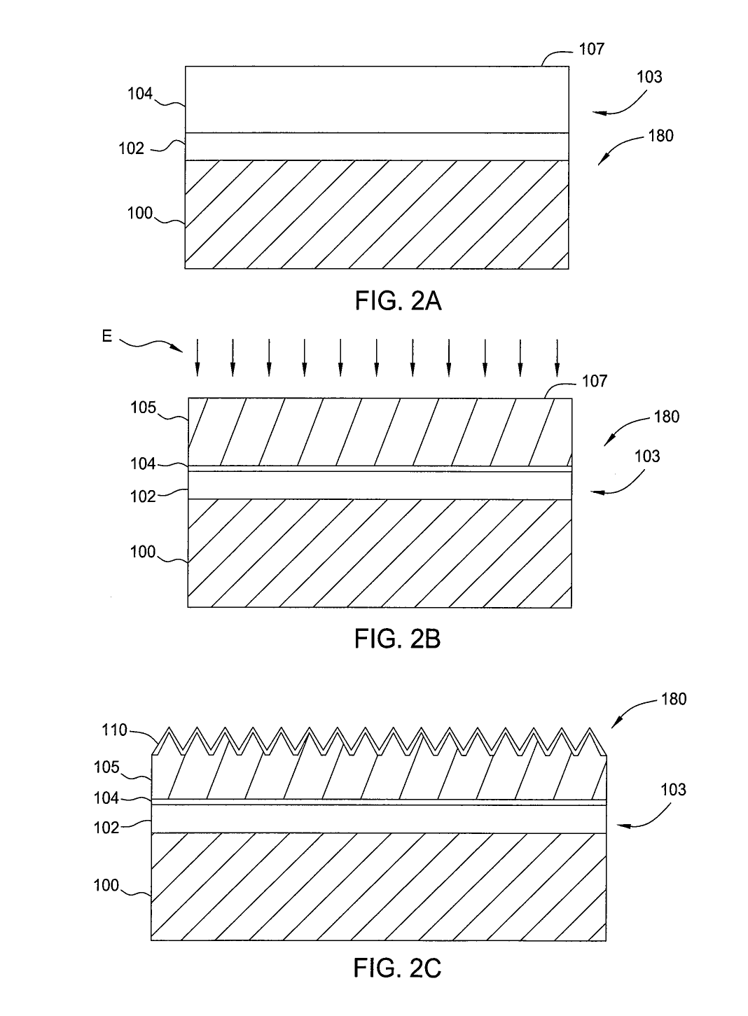

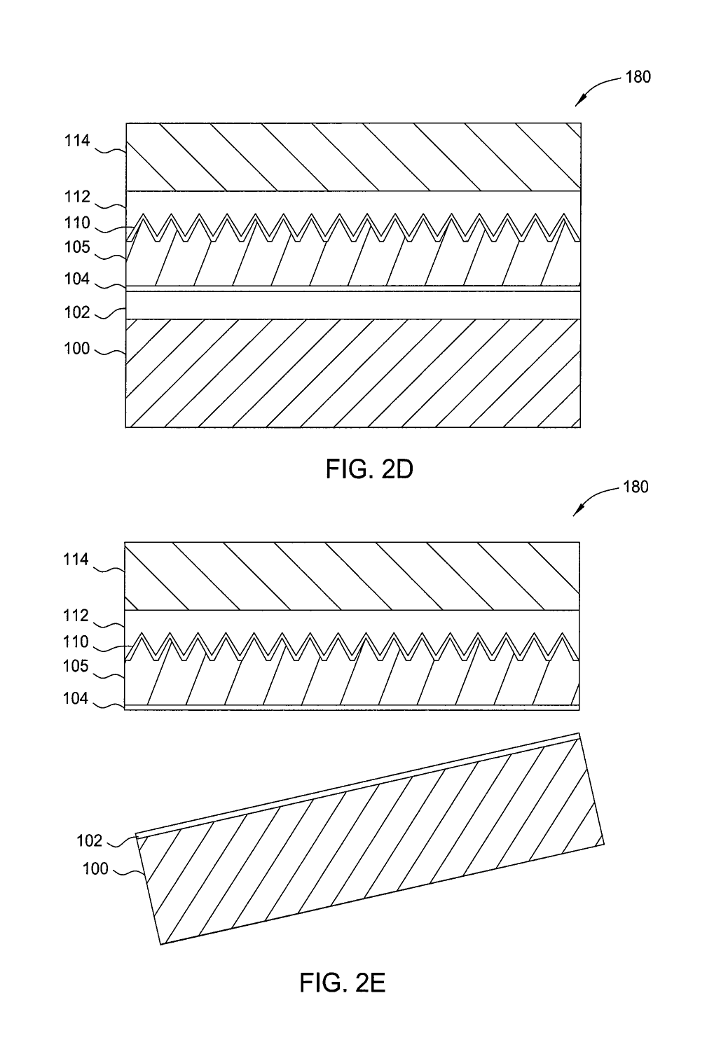

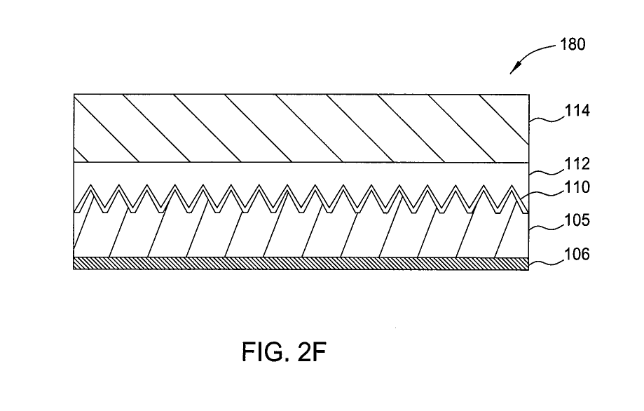

In another embodiment of the invention, a variation of the processing is used to form a thin high-efficiency back-junction solar cell device. The processing sequence is illustrated and further described in conjunction with FIGS. 2A-2F, which are schematic cross-sectional views that illustrate a solar cell structure during different stages of the processing sequence used to form a solar cell 180. The processes for forming the solar cell may be performed in a single process performed in one substrate processing chamber, or in multiple process steps performed in one or more processing chambers.

The process generally includes forming a crystalline layer over a porous layer formed on a silicon growth substrate. The formed crystalline layer and/or silicon growth substrate may be further processed to form various features such as rear emitters and anti-reflective coating/passivation layers. The growth substrate is separated from the formed crystalline layer, followed by completing the solar cell production process, such as forming the back contacts. In this configuration, the formed crystalline layer is the thin solar cell substrate, for example, between 10 and about 100 micrometers (μm) thick, on which the rest of the solar cell device structures are formed. The growth substrate may be reused multiple times to form many thin solar cell devices as previously described. In one embodiment, the silicon growth substrate may go through two dozen or more cycles to form thin single crystalline silicon films for solar cells.

Similar to the previous embodiment, the silicon growth substrate 100 may be a mono-crystalline Czochralski-grown p-type silicon substrate or other types of doped or undoped mono-crystalline silicon substrates may also be used. In order to make the single crystalline silicon growth substrate 100 reusable, a mechanically weak planar layer is formed over a surface of the growth substrate 100 so that a cleavage plane is disposed between the growth substrate 100 and a thin single crystalline silicon film formed thereon. A porous layer 103 is formed on a growth substrate 100 as previously described in conjunction with FIG. 1A. The low porosity top layer 104 may be between about 10 and about 100 micrometers (μm) thick, such as between about 40 and about 50 μm thick, and the high porosity bottom layer 102 may be between about 10 nanometers (nm) and about 5 μm thick. The cleavage plane may also be formed using the hydrogen implant process previously described.

Next, a region of the low porosity top layer 104 is thermally processed to form a recrystallized layer 105. The thermal processing may form the recrystallized layer 105 either through solid-phase densification of the pores, or by melting the material in the low porosity top layer 104 to some depth less than or equal to the depth of the low porosity top layer 104. It is believed that the recrystallized layer 105 will be thinner than the original thickness of the low porosity top layer 104. The recrystallized layer 105 is a mono-crystalline layer, or single crystal layer, that is between about 1% and about 90% of the thickness of the low porosity top layer 104.

In one embodiment, the recrystallized layer 105 is formed by delivering an amount of electromagnetic energy “E” (FIG. 2B) to the surface 107 the low porosity top layer 104 by an energy source. In general, the electromagnetic energy “E” delivered to the surface 107 of the low porosity top layer 104 is used to melt, sinter and/or recrystallize at least a portion of the low porosity top layer 104, so that a single crystalline layer is formed. In this case, the crystalline structure of the material found in the low porosity top layer 104 (i.e., porous single crystal material) is used as a seed layer to promote the growth of the single crystalline recrystallized layer 105 that has a morphology similar to the growth substrate 100.

In general, the energy source used to form the recrystallized layer 105 may be any directed energy source that can provide sufficient energy to melt, sinter and/or recrystallize a portion of the low porosity top layer 104. For example, the low porosity top layer may be thermally processed using a laser annealing process. Therefore, the recrystallized layer 105 is formed by irradiating the surface 107 of the low porosity top layer 104 with energy from a laser while the growth substrate 100 is disposed in a controlled atmosphere and maintained at temperatures below the melting point of silicon (e.g., temperature between 25° C. and 550° C.). The controlled atmosphere in which the substrate may be disposed during processing may be an inert atmosphere (e.g., blanket of an inert gas), a reducing atmosphere (e.g., H₂ containing atmosphere), or combinations thereof. The controlled atmosphere may also be at a sub-atmospheric pressure.

In one example, a pulsed laser, such as a green wavelength laser (Nd:YAG/YVO₄), an infrared (IR) wavelength laser (CO₂ laser), or an ultraviolet (UV) wavelength laser (Eximer laser) is used. The laser energy may be delivered at wavelength of about 532 nm or at about 1064 nm and a pulse frequency of the pulsed laser(s) may be between about 4 KHz and about 50 kHz. In one configuration, the energy density of laser light delivered to the substrate surface is between about 450 mJ/cm² and about 900 mJ/cm² that has a narrow full width at half maxima (FWHM). In one embodiment, the energy source is configured to deliver a combination of wavelengths of laser light to the surface 107 of the porous layer 104, such as by use of two or more laser sources having different emission wavelengths.

The growth substrate 100 is preheated to a desired temperature, such as between about 25° C. and about 550° C., to enhance the formation of the recrystallized layer 105. The growth substrate 100 may be preheated using a resistive heating element disposed in the stage on which the substrate is positioned during the process of delivering the electromagnetic energy. It is believed that preheating the growth substrate 100 can help improve the absorption of the delivered electromagnetic energy, due to the increased optical absorption of silicon materials as processing temperature increases, thus making it easier to control the thickness of the recrystallized layer 105 during processing.

Other energy sources that can be used to form the recrystallized layer 105 include a broadband light source (e.g., arc lamp), a flash lamp, an electron beam source, an IR heating element, a microwave source, or other similar device that is able to deliver sufficient energy to cause the formation of the recrystallized layer 105 from the porous layer 104. The energy source may be a line source or a point source, during which only portions of the surface 107 receive energy from the energy source for discrete times, which may sometimes be referred to as zone melt crystallization. The pores may be planarized by the zone melt recrystallization process. In one embodiment, the process of forming the recrystallized layer 105 is done by a zone refining type process in which an energy source (i.e., heating element) is scanned across the surface of the substrate. In addition, other techniques such as rapid thermal processing (RTP) may be employed to enhance the rate of recrystallization and/or the formation process. Thus, the entire surface 107 may receive energy from the energy source all at the same time.

Recrystallized layer 105 may also be doped either during the recrystallized layer 105 formation process or after forming the recrystallized layer 105, so that the formed layer has a desired doping level. In one embodiment, the recrystallized layer 105 is subsequently doped with an n-type dopant to form a heavily doped (n⁺ or n⁺⁺) region of the recrystallized layer 105.

The melting point of the material in the low porosity top layer 104 may be altered to promote the formation of the recrystallized layer 105. In one configuration, an amount of germanium (Ge) is doped into a silicon growth substrate 100 prior to the formation of the low porosity top layer 104 to reduce its melting point, thus allowing the preferential formation of the recrystallized layer 105. Thus, the growth substrate 100 may comprise a silicon substrate having a percentage of germanium evenly distributed therein or a silicon-germanium alloy in order to reduce the melting point of the low porosity top layer 104.

As shown in FIG. 2C, the top surface of the formed recrystallized layer 105 may be etched to form a textured surface The textured structure may also be further diffused with n-type dopant, such as phosphorous, to form a heavily doped n⁺ region near the textured surface followed by removal of any PSG formed on the recrystallized layer 105. An ARC layer 110 may be formed over the textured surface of the recrystallized layer 105, all of which may be done as described previously in conjunction with FIG. 1C. The ARC layer 110 may be formed to a thickness that allows it to help structurally support the thin recrystallized layer 105.

A mechanical support is then bonded to a surface of the recrystallized layer 105 to provide a support for the films formed during a lift off process to remove the growth substrate 100. The mechanical support may comprise various types of substrates, some of which may be used only as a carrier to be later discarded during the subsequent solar cell or solar module process and others that may form a portion of the completed solar cell or solar module. For example, a superstrate, such as a glass superstrate 114, is bonded to the ARC layer 110, as shown in FIG. 2D, using one or more of the processes previously described. The glass superstrate 114 serves as the front side glass in the final solar cell structure. The silicon growth substrate 100 is then separated from the partially formed solar cell 180, as shown in FIG. 2E, using one or more of the previously described processes in conjunction with FIG. 1E. The silicon growth substrate 100 may then be cleaned and reused.

A portion of the rear emitter structure is then formed by forming a p-type layer 106 within or on the recrystallized layer 105, as shown in FIG. 2F. The p-type layer 106 may be formed using a plasma doping process (e.g., P3i implant process available from Applied Materials Inc.), a standard diffusion process, a doped silicon layer deposition process (e.g., PECVD deposition process), or other similar doped layer formation process. In one embodiment, the formed p-type layer 106 has a high p-type doping level (e.g., p⁺ doping level). The p-type layer 106 will be used to form a p⁺ emitter in the solar cell 180.

Subsequent solar cell structure formation processes, such as formation of the rear emitters and back contacts can now be performed on the partially formed solar cell 180. Those processes are the same as described in conjunction with and shown in FIGS. 1G-1K. The solar cell is then tested to ensure functionality.

Embodiments of the invention generally provide a process of using a growth substrate to form a thin single crystalline silicon film that becomes the thin solar cell substrate on which the rest of the solar cell device is formed. The growth substrate is used to form a silicon bulk layer of epitaxial single crystalline silicon or a recrystallized layer of single crystalline silicon, followed by processing the silicon bulk layer or recrystallized layer to form the front side of the solar cell followed by the back side. In other embodiments, as discussed herein, the back side may be formed prior to front side processing. Thus, after formation of the silicon bulk layer 108 or recrystallized layer 105 on the silicon growth substrate 100, either the front side or the back side of the solar cell may be fabricated. Formation of the back side structures of a solar cell prior to the front side structures will now be described.

### Back-junction Cell with Double Transfer

This embodiment produces the back-junction cell structure prior to removal of the silicon growth substrate. The advantage of this approach is that the critical junctions on the rear surface of the back-junction solar cell can be fabricated at elevated temperatures and thus prior to removal of the silicon growth substrate. The thin single crystalline silicon film is transferred to a temporary carrier for completion of the solar cell processing, and then bonded to a glass superstrate. Although the subsequent embodiments and Figures use the silicon bulk layer 208 to describe back side solar cell processing done prior to separating the thin single crystalline film from the growth substrate for front side processing, the recrystallization layer 105 described in FIGS. 2A-2F may also be used in place of the silicon bulk layer 208.

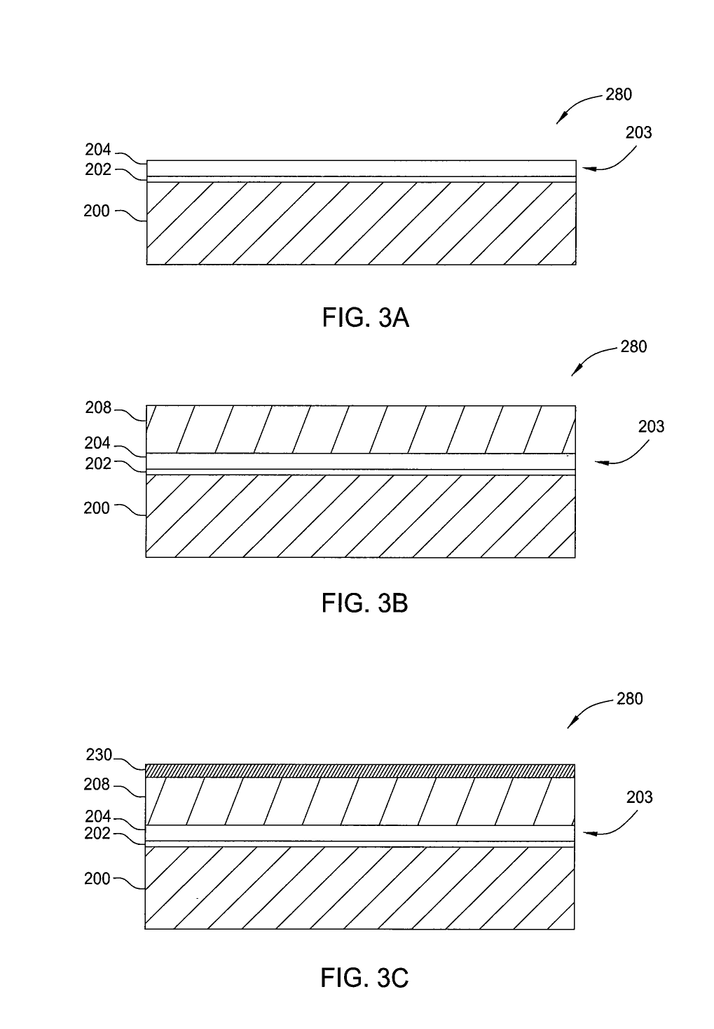

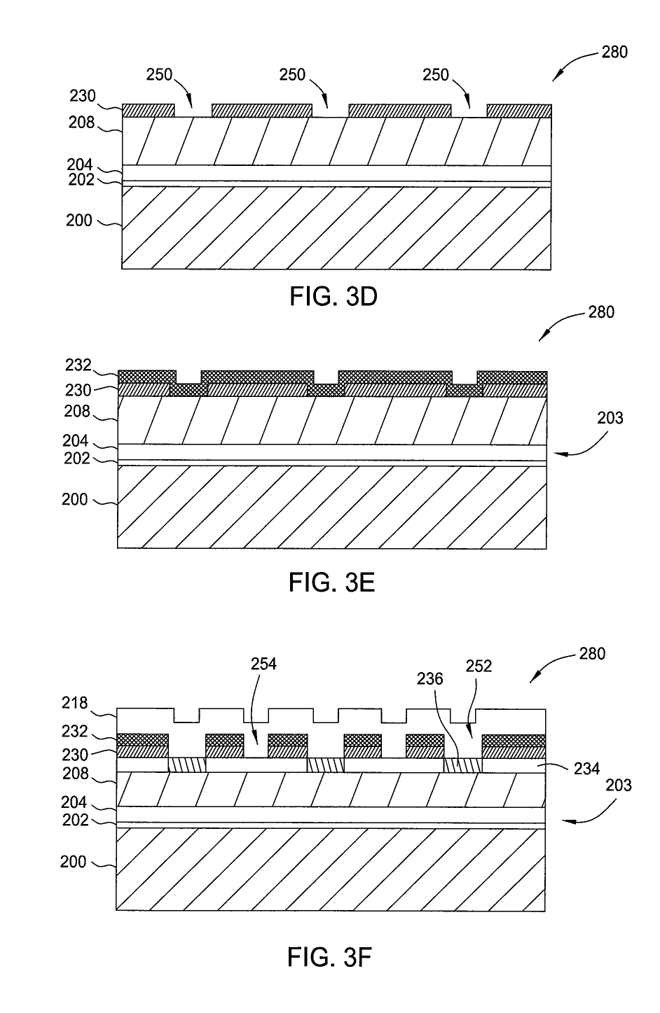

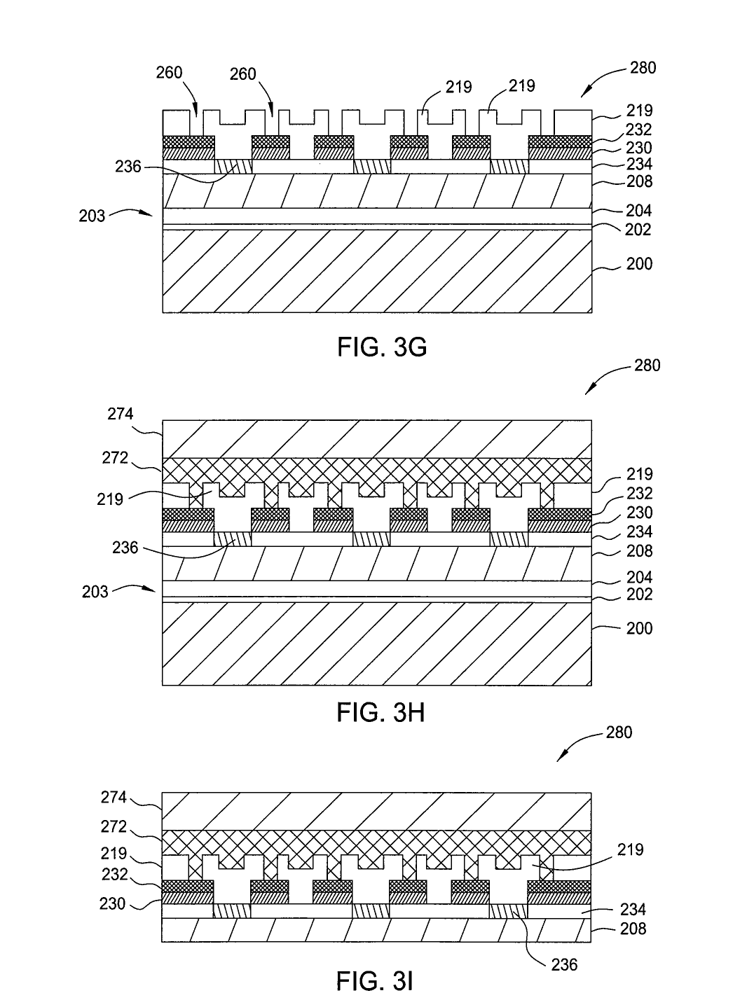

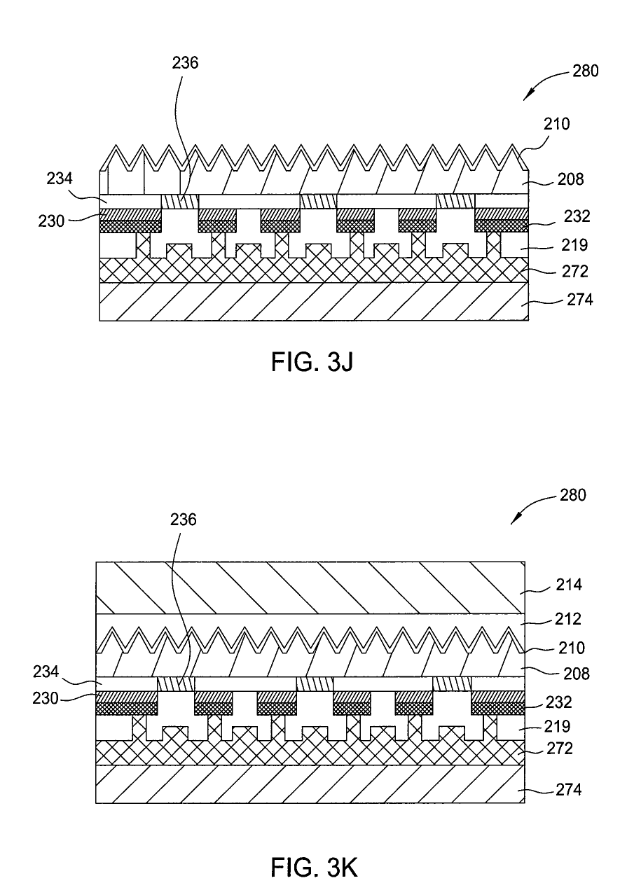

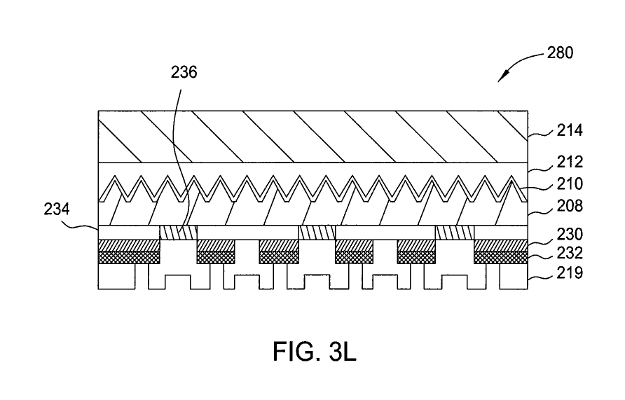

FIGS. 3A-3L illustrate schematic cross-sectional views of a solar cell substrate 200 during different stages in a processing sequence used to form a solar cell 280. As previously described, the silicon growth substrate 200 may be a mono-crystalline Czochralski-grown p-type silicon substrate or other types of grown p-type mono-crystalline substrates. The process sequence used to form the solar cell 280 generally begins by forming a porous layer 203 on a growth substrate 200 (FIG. 3A) as previously described.

A silicon bulk layer 208 of epitaxial single crystalline silicon is formed on the porous layer, for example the low porosity top-layer 204, as shown in FIG. 3B, using the one or more of the previously described processes. The epitaxial silicon bulk layer 208 may be from 10 to 50 microns thick, such as 40 microns thick, and is doped with an n-type dopant during the formation process. The epitaxial formation of a thin film of silicon on the growth substrate 200 creates a silicon bulk layer 208 that has the same crystal structure of the growth substrate 200. Thus, a thin single crystalline silicon film may be formed on the growth substrate 200 using the porous layer 103 as a seed layer.

The rear emitter is then formed using processes as shown in FIGS. 3C-3F. A borosilicate glass (BSG) layer 230 is formed on the epitaxial silicon bulk layer 208 as shown in FIG. 3C. The BSG layer may be formed by atmospheric pressure CVD (APCVD), spin coating, a printed paste, or other methods known in the art. APCVD may be beneficial because no organic compounds are necessary. The BSG layer is the boron diffusion source for forming the p-type contacts. Other p-type layers may also be formed to provide the p-type diffusion source.

Contact openings 250 are formed in the BSG layer 230 to eventually form n-type contacts, as shown at FIG. 3D. A portion of the p-type BSG layer 230 is removed, exposing the epitaxial silicon bulk layer 208. The BSG layer may be patterned using laser ablation, patterned etchant, patterned resist, lithographic processes, an etch gel, or other suitable patterning techniques known in the art. When using the printed paste, the patterning step is not necessary to form the contact openings.

Next, a PSG layer 232 is formed over the BSG layer 230 and the openings 250, as shown in FIG. 3E. Like the BSG layer, the PSG layer may be formed by APCVD, spin coating, a printed paste, etc. In one embodiment, an undoped glass layer, such as silica, may be formed on either or both the BSG and PSG layers 230, 232 to cap the doped glass layers and thereby control the interaction between the dopants. The PSG layer 232 provides an n-type diffusion source, such as phosphorous, that will be used to form the n-type contacts.

The partially formed solar cell 280 is then subjected to a drive-in/oxidation process at around 1000° C. to drive-in the p-type and n-type dopants and form p-type emitters 234 and n-type emitters 236 in a region of the epitaxial silicon bulk layer 208, such as near the surface of the epitaxial silicon bulk layer 208, as shown in FIG. 3F. The high temperature drive-in/oxidation process may provide a nominal diffusion depth of about 1 to 1.5 microns. The deposited oxide layers (BSG and PSG) may serve as passivation layers after the high temperature drive-in/oxidation. Thus, they will remain as the rear surface passivation layer. In an alternative embodiment, a patterned etch using dopants as previously described, may be used to form the p-type and n-type emitters.

The back contacts 219, such as p-type and n-type contacts, are formed as illustrated in FIGS. 3F-3G. To form the back contacts 219, the BSG layer 230 and PSG layer 232 are patterned to form p-type contact openings 252 and n-type contact openings 254 using laser ablation, printed etchants, resist and etchant, or other suitable patterning techniques. The openings are formed in the BSG layer 230 and PSG layer 232 to expose the p-type emitters 234 and n-type emitters 236 formed in a region of the epitaxial silicon bulk layer 208, such as near the surface of the epitaxial silicon bulk layer 208.

The back contacts 219 may be formed by deposition of a thin-film metallization layer 218. The thin-film metallization layer may be, for example, Al which may then be coated with a more bondable metal such as Ni. Metallization of the rear surface of the solar cell 280 may include metallization of the PSG layer 232 and p-type emitters 234 and n-type emitters 236. Next, the metallization layer 218 is patterned to form openings 260, thereby forming the back contacts 219, such a p-type and n-type contacts, which becomes a circuit layer. The openings 260 may be formed using etchant gels or other suitable techniques. The back contacts 219 may be annealed or sintered at temperatures compatible with the rest of the films in the solar cell structure, such as below 400° C., for example between about 300° C. and about 400° C. The annealing or sintering may be done using non isothermal rapid thermal techniques, such as RTP systems, or a short heat pulse from one surface, or sub-band gap light and optical processing, so that the light and thus the heat is selectively absorbed by the contacts. The p-type contact may be done as a LFC which may eliminate the p-type contact patterning step, and use the laser firing step as an alternative. The p-type contacts and n-type contacts are thus electrically connected to the respective p-type emitters and n-type emitters formed in solar cell 280.

The partially formed solar cell 280 is then coupled to a temporary carrier 274 as shown in FIG. 3H. The temporary carrier 274 may be another silicon substrate or a glass substrate. An adhesive layer 272 is used to bond the temporary carrier 274 to the rear surface of the solar cell, such as the back contacts 219 and PSG layer 232. Any adhesive material compatible with subsequent solar cell formation processes may be used. In one embodiment the adhesive layer may be a wax material. Thus, using a temporary carrier 274 enables formation of the front side structure of the solar cell 280 after separation of the growth substrate 200 from the partially formed solar cell 280.

The silicon growth substrate 200 is then separated from the silicon bulk layer 208, as shown in FIG. 3I. This is done by cleaving the growth substrate 200 from the solar cell 280 along the boundary between the low porosity top porous layer 204 and the high porosity bottom porous layer 202. After the silicon growth substrate 200 is removed, the low porosity top-layer 204 is removed from the silicon bulk layer 208, such as by etching and cleaning the surface. The silicon growth substrate 200 may then be reused.

The front surface of the silicon bulk layer 208, i.e. the surface opposite temporary carrier 274, may then be etched to form a textured surface as shown in FIG. 3J following which an anti-reflection coating (ARC) layer 210 may be formed on the textured surface of the silicon bulk layer 208, as shown in FIG. 3J. The ARC layer 210 may be a silicon nitride layer formed as previously discussed. The textured silicon bulk layer 208, which may include the ARC layer 210, is then attached to a superstrate, such as a glass superstrate 214 as shown in FIG. 3K. In one embodiment, the glass superstrate 214 may be bonded to the silicon bulk layer 208 by using an adhesive such as silicon, thereby forming adhesive layer 212. When using silicone, the solar cell 280 may then be baked in an oven at 200° C. to complete the bonding process and cure the adhesive layer 212 to the glass superstrate 214. Other appropriate adhesive materials known in the art may also be used. The glass superstrate may be a thin sheet that is from 100-1,000 microns thick and similar to the glass superstrate previously described. The glass superstrate 214 supports the silicon bulk layer 208, and can be handled similar to a standard silicon substrate. The temporary carrier 274 is then removed from the completed solar cell 280, exposing the back contacts 219, as shown in FIG. 3L.

An ILD layer (not shown) might optionally be printed over the metallization layer and back contacts 219 at this point to provide electrical isolation in a module assembly as previously described. One advantage of forming an ILD layer towards the end of the process is that the resist material used to form the ILD layer likely has the lowest temperature tolerance of any material in the solar cell assembly. The solar cell assembly may then be used to form a solar module.

### Back-Junction Solar Cell on Substrate with Via Holes

In this embodiment, the back-junction cell structure is formed while the thin single crystalline silicon film is still on the growth substrate and the thin single crystalline silicon film is then bonded to a substrate that will be incorporated into the final package module. A substrate with via holes that are aligned over the back contacts on the solar cell may be used. The finished back-junction solar cell is then assembled into a module using monolithic module assembly (MMA). The holes in the substrate will provide areas where the electrical attachment can be made to the MMA flexible-circuit backsheet.

MMA provides an ideal process for assembling the back-junction thin single crystalline silicon film solar cells into a module. MMA refers to the assembly of the module electrical circuit and laminate construction in the same step. The flexible-circuit backsheet of MMA extracts current from the solar cell at many distributed points, which minimizes the grid resistance in the solar cell and enables use of the thin-film metallization. MMA is more compatible with thin solar cell assembly than conventional module assembly using stringer/tabber tools because the module construction is more planar. MMA enables making the electrical circuit in the module and encapsulation done all during the lamination step for single step module assembly. Some advantages of MMA include a more planar geometry which is more compatible with thin solar films, an inherently more gentle interconnect using ECA, and the copper foil in the flexible-circuit backsheet is more flexible than stiff copper ribbons in standard solar cell assembly.

The high resistance of the thin-film metallization on the thin crystalline-silicon film solar cell requires extraction of the current at many points on the interior of the solar cell. This minimizes the average distance for current collection, which thereby minimizes resistance losses in the metallization. The module assembly technology should also minimize stress on the thin single crystalline silicon film solar cell, and take advantage of the back contact geometry to reduce cost and simplify the assembly process.

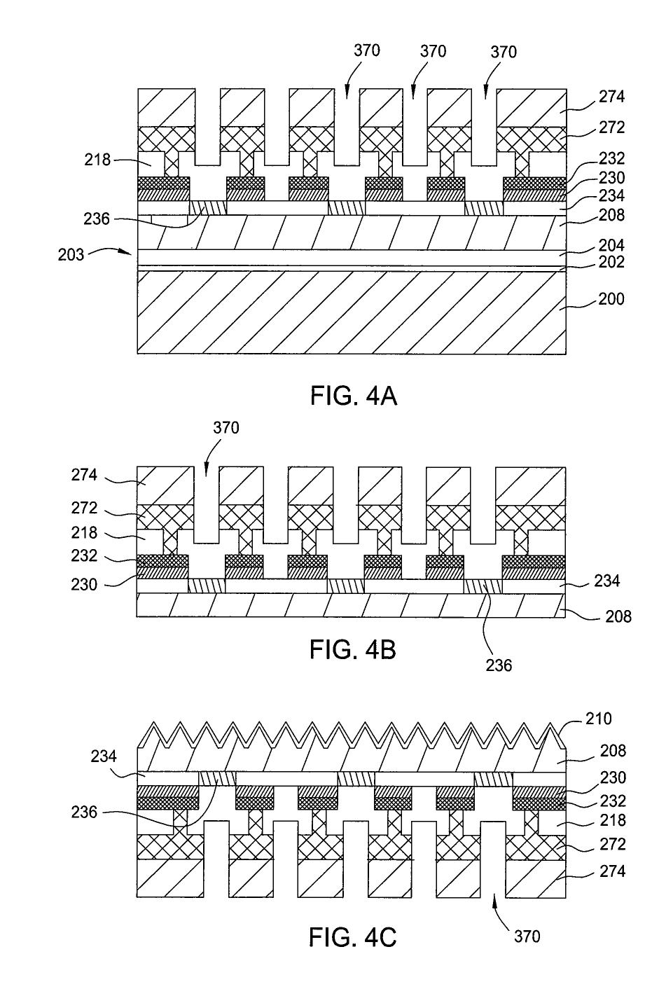

The back-junction solar cell formation processes described with respect to FIGS. 3A-3G may be used to form a solar cell 280. Instead of coupling a temporary carrier to the solar cell 280, however, other types of substrates may be coupled to the solar cell. For example, the substrate may be a substrate 373 having via holes 370 that are aligned over the back contacts, as shown in FIG. 4A, to provide areas where the electrical attachment can be made to the MMA flexible-circuit backsheet.

The substrate 373 may be bonded to the solar cell 280 with an adhesive, thereby forming an adhesive layer 272. As previously described, this material might be silicone or other bonding material with suitable electrical, chemical, and mechanical properties. The adhesive layer preferably should not occlude the vias where the electrical interconnects for the solar cell will be fashioned.

An interlayer dielectric (ILD) (not shown) may also be formed, for example, by screen printing, over the back contacts 219 prior to coupling the substrate 373 to the solar cell 280. The ILD layer may be patterned to include vias that will align with the via holes 370 in the substrate and permit contact with the back contacts 219. The ILD is attached to the substrate 373 using any suitable technique and material, such as those previously described. For example, various polymers may be used as an adhesive to couple the ILD layer to the substrate 373. In one embodiment, the vias in the substrate may provide sufficient electrical isolation of the electrical interconnect so as to eliminate the need for an ILD layer. As similarly described above, using the substrate 373 enables formation of the front side structure of the solar cell 280 after separation of the growth substrate 200 from the silicon bulk layer 208.

The silicon growth substrate 200 is separated from the solar cell 280, as shown in FIG. 4B. After the silicon growth substrate 200 has been removed, the low porosity top-layer 204 is removed from the silicon bulk layer 208 and the silicon growth substrate 200 is prepared to be reused in the solar cell formation process.

The top surface of the silicon bulk layer 208, i.e. the surface opposite the substrate 373, may then be etched to form a textured surface as shown in FIG. 4C, using processes previously described. An ARC layer 210 is formed on the textured surface of the epitaxial silicon bulk layer 208, as shown in FIG. 4C. The final processing steps are not shown, but may include assembly into a module using MMA, where the holes 370 in the substrate 373 are used for electrical connection of the MMA flexible-circuit backsheet.

### Back-junction Cell on MMA Substrate

This process forms the back-junction solar cell while the thin single crystalline-silicon film is still on the silicon growth substrate as well. The thin crystalline-silicon film is then electrically and mechanically bonded to a substrate with a matching electrical circuit, e.g. the MMA flexible-circuit backsheet for an individual solar cell. A representative back-junction thin crystalline-silicon film solar cell fabrication process into using an MMA substrate is illustrated in FIGS. 4A-4B.

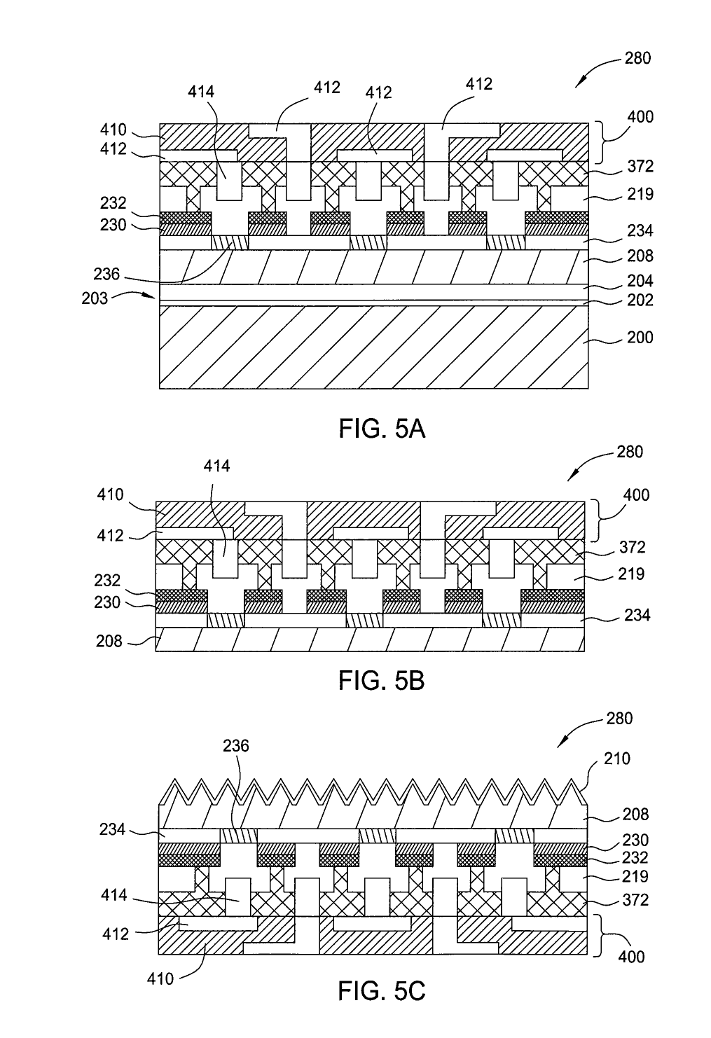

The back-junction solar cell formation processes described with respect to FIGS. 3A-3G may be used to form a solar cell 280. In this embodiment, the substrate coupled to the back contacts 219 may be formed from a rigid material rigid. The substrate could potentially use the same substrate material that is commonly used for printed-circuit boards (FR4). In some embodiments the substrate may be a printed-circuit board (PCB) 400 having electrical contacts 412 and dielectric material 410 such as FR4, as shown in FIG. 5A. An adhesive may be formed between the printed circuit board 400 and the solar cell 280, thereby forming an adhesive layer 372. An electrically conductive material may be screen printed on the solar cell 280 to form electrical contacts 414 to electrically connect the PCB 400 with the solar cell 280. The electrically conductive material may be an ECA or a low temperature solder material, which may be formed using a stencil print, a dispense method (micro injector dispenser), or other methods known in the art. The ECA may be a silver loaded epoxy type material. Other materials may be silver-particle loaded silicones as well as epoxy material loaded with low temperature solder particles. An adhesive material and/or encapsulant may be used to couple the substrate to the solar cell by curing or laminating the assembly. The PCB 400 and the solar cell form a mini module circuit. An ILD layer (not shown) may also be applied either to the solar cell and/or to the printed circuit board to improve the electrical isolation around the areas of the electrical interconnect 414.

After attaching the solar cell 280 to the PCB 400 and separating the growth substrate 200 from the silicon bulk layer 208, the remaining front surface formation processes may be performed as described above with respect to FIGS. 3J-3L and shown in FIGS. 5B-5C. The silicon growth substrate 200 is separated from the solar cell 280, as shown in FIG. 4B. After the silicon growth substrate 200 has been removed, the low porosity top-layer 204 is removed from the silicon bulk layer 208 and the silicon growth substrate 200 is prepared for reuse.

The top surface of the epitaxial silicon bulk layer 208, i.e. the surface opposite the PCB 400, may be etched to form a textured surface as shown in FIG. 4B, using processes previously described. An ARC layer 210 is formed on the textured surface of the silicon bulk layer 208, as shown in FIG. 5C.

The module assembly then follows a similar procedure used with conventional crystalline silicon solar cells e.g. the thin-silicon film solar cells on the printed circuit board are assembled into strings, the strings are laid up with the sheets of encapsulant, glass, and backsheet, and the stack of materials and solar cell circuit is then laminated to form a completed module assembly.

### Module-Scale Integration

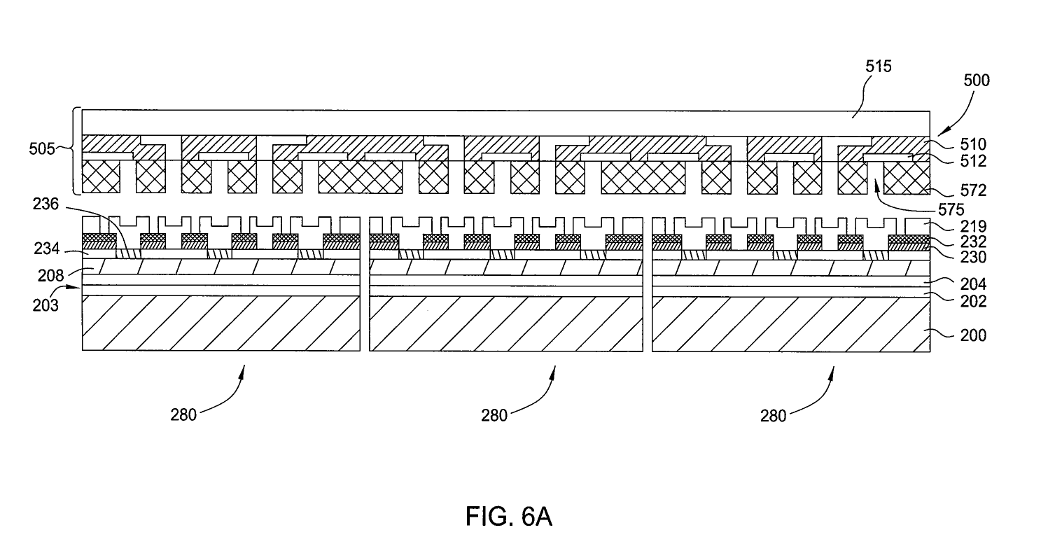

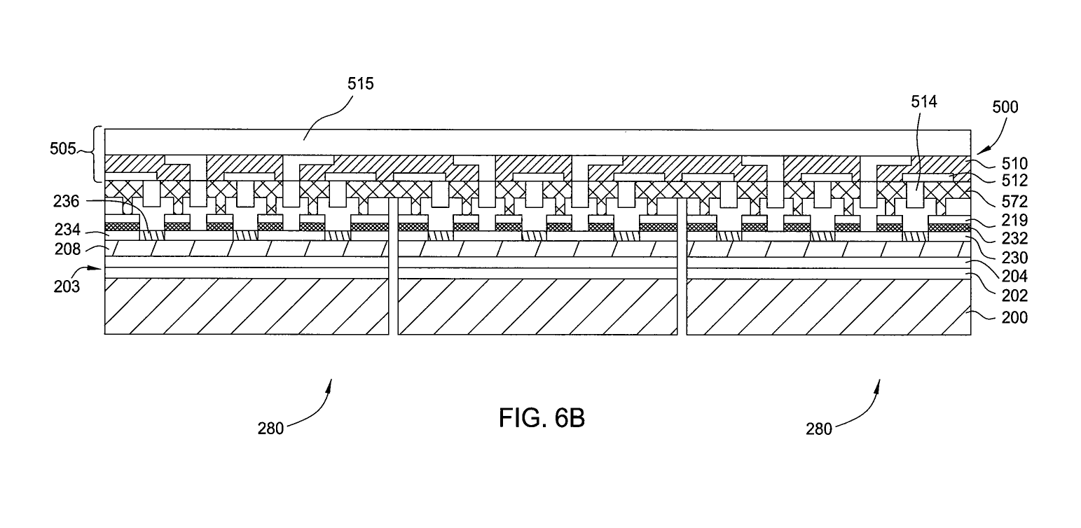

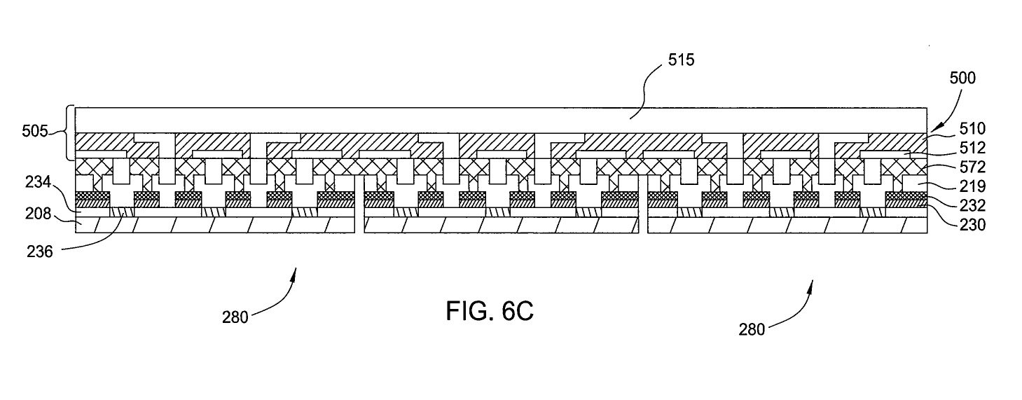

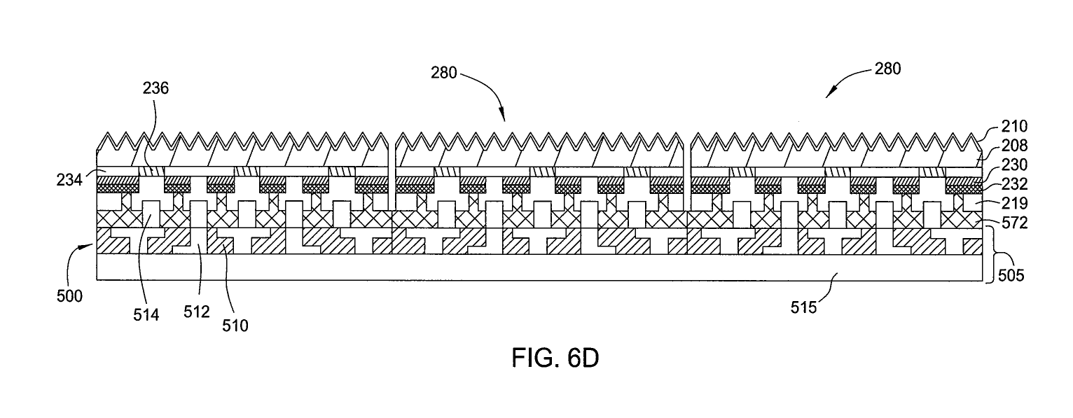

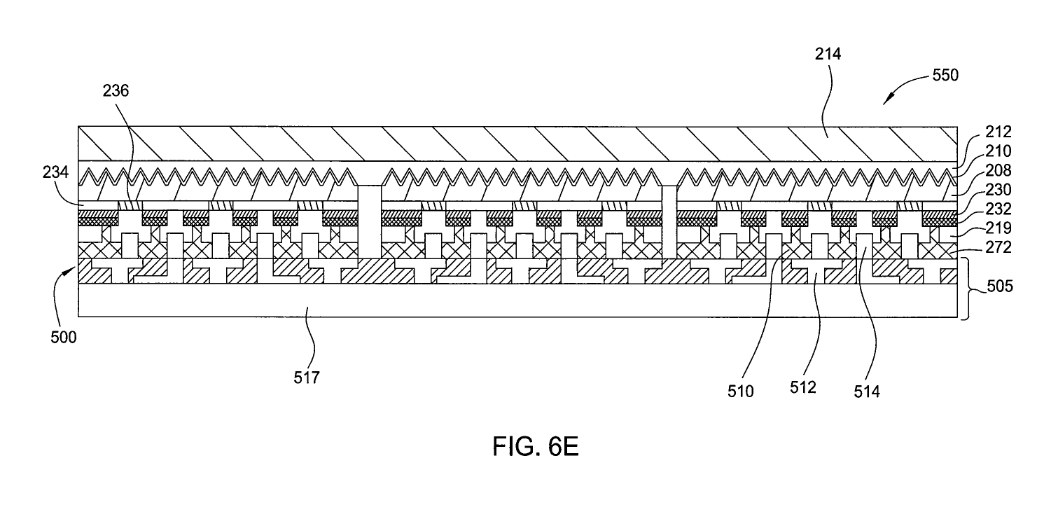

The embodiments described thus far include a mechanical support bonded to the thin single crystalline silicon film that is substrate-sized. This process sequence bonds the thin single crystalline silicon film of multiply partially formed solar cells to a mechanical support, such as an MMA sub-assembly, and then separates the film from the silicon growth substrates, followed by attaching the module glass to the thin singly crystalline silicon film. This process eliminates the cost of the carrier. However, the completion of the cell processing and module assembly may all need to be completed on a module-sized glass sheet—typically 1.5 to 2 m². A module may include 60 or 72 solar cells. A representative process that fabricates a back-junction solar cell and uses MMA is illustrated in FIGS. 6A-6E.

Formation of the rear solar cell structures as previously described in the back-junction solar cell formation processes with respect to FIGS. 3A-3G are performed. In one embodiment, an ILD layer (not shown) might optionally be printed over the metallization layer and back contacts 219 to provide electrical isolation in the module assembly. Multiple solar cells 280 may then be coupled with a substrate larger than an individual solar cell, such as an MMA sub-assembly 505.

The substrate, such as MMA sub-assembly 505, is attached to multiple partially formed solar cells 280. The MMA sub-assembly 505 may be formed by laying up the MMA backsheet 515 with a PCB 500 having electrical contacts 512 and dielectric material 510 such as FR4, punching an encapsulant 572 to form holes 575, and laying up the encapsulant 572 with the MMA backsheet 515 and PCB 500 to align the holes 575 with the electrical contacts 512. The backsheet 515 forms a protective planar outer layer that provides environmental protection for the solar cell module and has the same area as the desired module area. The MMA sub-assembly 505 is then aligned over multiple partially formed solar cells 280, as shown in FIG. 6A.

An adhesive, such as electrically conductive adhesive (ECA), is then applied on the solar cell to form electrical contacts 514, as shown in FIG. 5B. The ECA, MMA sub-assembly 505, and the solar cells 280 are then laminated and cured to encapsulate the back contacts 219, as shown in FIG. 6B. After attaching the partially formed solar cells 280 to the MMA sub-assembly 505, the remaining front surface formation processes may be performed as described above and shown in FIGS. 6C-6D to complete formation of the solar cells. The silicon growth substrates 200 are separated from the silicon bulk layers 206 of the multiple solar cells 280, as shown in FIG. 6C. After the silicon growth substrate 200 has been removed, the low porosity top-layer 204 is removed from the silicon bulk layer 208 of the solar cells 280 and the silicon growth substrate 200 is prepared for reuse.

The top surface of the epitaxial silicon bulk layer 208 of each solar cell 280, i.e. the surface opposite the MMA sub-assembly 505, may be etched to form textured surfaces as shown in FIG. 6D, using processes previously described. ARC layers 210 are formed on the textured surfaces of the epitaxial silicon bulk layers 208, as shown in FIG. 6D. The module is completed as shown in FIG. 6E. The textured epitaxial silicon bulk layers 208 of each solar cell 280 are coupled to a superstrate, such as a glass superstrate 214. The glass superstrate 214 is sufficiently large to cover the entire solar cell module 550. The glass superstrate 214 is bonded to the silicon bulk layers 208 by using an adhesive, such as silicone or other encapsulant, thereby forming adhesive layer 212.

Formation of solar module 550 may be completed using known techniques and processes. For example, the entire structure may be laminated and excess material trimmed off around the glass superstrate 214. The module 550 may be completed using known processes, including attaching a module termination and Junction-box (J-box) by bringing the leads out of the circuit and terminating them in the J-box, which has electrical connections with other modules in the system, followed by framing and testing the solar cell module.

### Front and Rear Contact Structure Solar Cell with Glass Superstrate

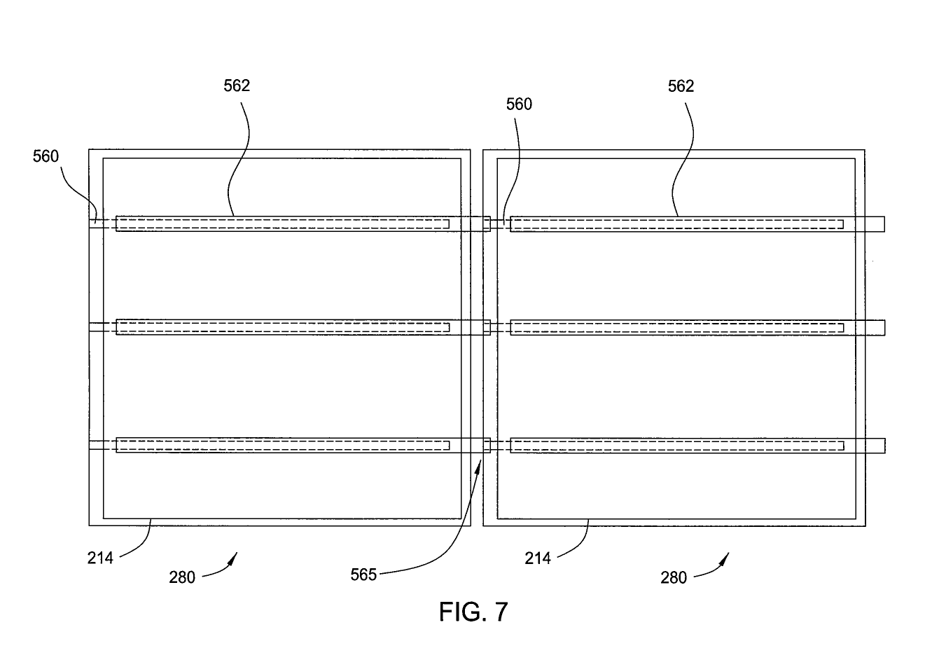

This process produces a solar cell using the thin crystalline-silicon film with a front and back contact cell structure. The front surface of the solar cell is processed while the single crystalline silicon film is still on the silicon growth substrate. The solar cells are then connected in series using copper interconnects when forming a module, as illustrated in FIG. 7.

The process sequence used to form a solar cell 280 generally begins by forming a porous layer 203 on a growth substrate followed by formation of a silicon bulk layer 208 on the porous layer, as previously described. Further front side processes are performed, such as texturing and forming a passivation layer. Next, silver (Ag) grids are formed on the front surface followed by formation of a copper interconnect on the front surface. The Ag grids may be formed by a screen print and fire using a Ag-paste metallization process. Copper interconnects are formed over the front surface of the solar cell and over the silver grids formed as the front side contacts on the solar cell. Thus, the copper interconnects may be connected with the top surface of the solar cell. For example, the front copper interconnects may be connected to the silver grid front contacts. The copper interconnects may be a copper strip or copper foil.

The solar cell is then coupled to a superstrate. The superstrate may be glass and bonded to the solar cell using an adhesive as previously described. The front surface copper interconnects 560 are thereby placed between the glass superstrate 214 and silicone, which may have a similar structure as shown in FIG. 1D. The copper interconnects may extend out a little distance on one side of the die and may match the die size. For example, as shown in FIG. 7, the front copper interconnects 560 sandwiched between the glass superstrate 214 and the solar cell 280 in silicone (not shown) extends out from the front side of the solar cell and towards the edge of the glass superstrate 214 but does not extend to the other side of the glass superstrate 214.

The solar cell is then removed from the silicon growth substrate. The cell is completed with application of a passivation layer and back contacts on the rear surface. In this embodiment, the back contacts may be all of one type, e.g. p-type contacts, while the front contacts made with the Ag grid may be of the opposite type, e.g. n-type contacts.

The rear copper interconnects are then formed on the rear surface of the solar cell. Similar to the front copper interconnects 560, the rear copper interconnects 562 are coupled with the rear surface of the solar cell 280 and may extend out a little distance on the other side of the die opposite the front side interconnects. For example, as shown in FIG. 7, the rear copper interconnects 562 extend out from the rear side of the solar cell 280 and beyond the edge of the glass superstrate 214 but may not extend to the other side of the glass superstrate 214 having the front copper interconnects 560. Two or more solar cells 280 are then connected in series. The copper interconnect 562 formed on the rear surface is connected to the front copper interconnect 560 of an adjacent solar cell, such as at a connection point 565. The negative and positive polarity contacts of adjacent solar cells are thereby connected in series.

The module may be assembled in a manner similar to a conventional module assembly, e.g. the cells are assembled into strings, the strings are laid up with the sheets of encapsulant, glass, and backsheet, and the stack of materials and solar cell circuit is then laminated. It should be noted that this process could be performed with the thin crystalline-silicon films bonded to the full-module-sized glass rather than a cell-sized glass.

While the foregoing is directed to embodiments of the invention, other and further embodiments of the invention may be devised without departing from the basic scope thereof.

What is claimed is:

1. A method of forming a solar cell, comprising:
forming a cleavage plane on a growth substrate;
forming an epitaxial silicon bulk layer on the cleavage plane;
forming portions of a solar cell structure on and/or in the epitaxial silicon bulk layer;
attaching a mechanical support to the epitaxial silicon bulk layer opposite the growth substrate;
separating the growth substrate from the epitaxial silicon bulk layer along the cleavage plane; and
forming other solar cell features on and/or in the epitaxial silicon bulk layer opposite the mechanical support to complete formation of the solar cell structure.

2. The method of claim 1, wherein forming the cleavage plane on a growth susbtrate comprises:
forming a porous layer on the growth susbtrate.

3. The method of claim 2, wherein forming the porous layer on the growth substrate comprises:
electrochemically etching the growth substrate; and
annealing the substrate in hydrogen gas.

4. The method of claim 3, wherein the electrochemical etching comprises an electrolyte solution comprising about 2 wt % of HF.

5. The method of claim 2, wherein forming the porous layer on the growth substrate comprises:
forming a bottom porous layer having a first porosity on the growth susbtrate;
and
forming a top porous layer having a second porosity on the bottom porous layer, wherein the first porosity is greater than the second porosity.

6. The method of claim 5, wherein forming the epitaxial silicon bulk layer further comprises:
forming a p-type layer on the top porous layer.

7. The method of claim 6 wherein forming other solar cell features on and/or in the epitaxial silicon bulk layer opposite the mechanical support to complete formation of the solar cell structure further comprises:
forming rear emitters in the epitaxial silicon bulk layer opposite the mechanical support; and
forming contacts on the rear emiters.

8. The method of claim 1, further comprising:
reusing the growth substrate to form another epitaxial silicon bulk layer for formation of another solar cell.

9. The method of claim 1, wherein the epitaxial silicon bulk layer has the same crystal structure as the growth susbtrate.

10. The method of claim 1, wherein forming portions of a solar cell structure on and/or in the epitaxial silicon bulk layer further comprises:
texturing a surface of the epitaxial silicon bulk layer opposite the growth substrate;
forming an ARC layer on the textured epitaxial silicon bulk layer.

11. The method of claim 2, wherein forming a cleavage plane on a growth susbtrate further comprises:
implanting hydrogen ions in the porous layer; and
annealing the growth substrate and the porous layer to recombine the hydrogen atoms.

12. A method of forming a solar cell, comprising:
forming a porous layer having a cleavage plane on a growth substrate;
forming an epitaxial silicon bulk layer on the porous layer;
forming rear emitters in the epitaxial silicon bulk layer;
forming back contacts on the rear emitters;
coupling the back contacts with a mechanical support;
separating the growth susbtrate from the mechanical support along the cleavage plane;
forming an ARC layer on the epitaxial silicon bulk layer opposite the mechanical support; and
coupling the ARC layer with a glass superstrate.

13. The method of claim 12, wherein the mechanical support comprises one of a temporary carrier, a substrate having via holes, and a printed circuit board.

14. The method of claim 12, wherein the porous layer further comprises:
a bottom porous layer having a first porosity; and
a top porous layer having a second porosity, wherein the top porous layer has smaller pores than the bottom porous layer and wherein the first porosity is greater than the second porosity.

15. The method of claim 12, further comprising:
removing the mechanical support to expose the back contacts.

16. A method of forming a solar cell module, comprising:
forming two or more solar cells, each solar cell formed by a method comprising:
forming a porous layer on a growth substrate;
forming an epitaxial silicon bulk layer on the porous layer;
forming an ARC layer on the epitaxial silicon bulk layer;
forming grids on a front surface of the solar cell, the front surface having frontside contacts formed over the ARC layer;
forming interconnects over the front surface and the grids;
coupling the solar cell to a superstrate;
separating the growth susbtrate from the epitaxial silicon bulk layer;
froming back contacts on a rear surface opposite the front surface of the solar cell, wherein the back contacts are of a different type than the front contacts; and
forming interconnects over the back contacts and the rear surface;
connecting the two or more solar cells in series by connecting the interconnect formed over the rear surface of one of the two or more solar cells to the interconnect formed over the front surface of another of the two or more solar cells.

17. A method of forming a solar cell module, comprising:
partially forming two or more solar cells, each solar cell partially formed by a method comprising:
forming a porous layer having a cleavage plane on a growth substrate;
forming an epitaxial silicon bulk layer on the porous layer;
forming rear emitters in the epitaxial silicon bulk layer;
forming back contacts over the rear emitters;
coupling the back contacts of the two or more partially formed solar cells with a monolithic module assembly sub-assembly;
separating the growth susbtrates from the partially formed solar cells along the cleavage planes of each solar cell;
forming other solar cell features on and/or in the epitaxial silicon bulk layer of each partially formed solar cell opposite the mechanical support to complete formation of the solar cell structure for each solar cell;
attaching a glass superstrate to the epitaxial silicon bulk layer of each solar cell opposite the monolithic module assembly sub-assembly.

18. The method of claim 17, forming other solar cell features on and/or in the epitaxial silicon bulk layer of each partially formed solar cell opposite the mechanical support to complete formation of the solar cell structure for each solar cell comprises:
texturing a surface of the epitaxial silicon bulk layer of each partially formed solar cell opposite the monolithic module assembly sub-assembly;
forming an ARC layer over the textured epitaxial silicon bulk layers.

19. A solar cell, comprising:
an epitaxial silicon bulk layer formed using a growth substrate, the epitaxial silicon bulk layer having a front surface and a rear surface;
a p-type emitter comprising a p-type dopant formed in the rear surface of the epitaxial silicon bulk layer;
an n-type emitter comprising an n-type dopant formed in the rear surface of the epitaxial silicon bulk layer;
p-type contacts connected to the p-type layer; and
n-type contacts connected to the n-type layer.

20. A solar cell module, comprising:
two or more solar cells, each solar cell comprising:
an epitaxial silicon bulk layer formed using a growth substrate, the epitaxial silicon bulk layer having a front surface and a rear surface;
a p-type emitter comprising a p-type dopant formed in the rear surface of the epitaxial silicon bulk layer;
an n-type emitter comprising an n-type dopant formed in the rear surface of the epitaxial silicon bulk layer;
p-type contacts connected to the p-type layer; and
n-type contacts connected to the n-type layer
a glass superstrate attached to the epitaxial silicon bulk layers of the two or more solar cells; and
a monolithic module assembly sub-assembly coupled to the back contacts of the two or more solar cells.
